(19) United States
(12) Patent Application Publication
(10) Pub. No.: US 2010/0225334 A1
(43) Pub. Date: Sep. 9, 2010

(54) LIQUID CONCENTRATION SENSOR

(75) Inventors: Akikazu Uchida, Obu-city (JP); Hirotsugu Ishino, Toyokawa-city (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 12/719,349

(22) Filed: Mar. 8, 2010

(30) Foreign Application Priority Data
Mar. 6, 2009 (JP) 2009-53333

(51) Int. Cl. G01R 27/26

(52) U.S. Cl. 324/663

(57) ABSTRACT

A liquid concentration sensor includes an electrode capacitance conversion circuit, a stray capacitance conversion circuit and a difference calculation circuit. The electrode capacitance conversion circuit includes a detection electrode and a switching device. The detection electrode has a pair of opposing terminals and is partially located in a liquid fuel. The switching device is turned ON and OFF to switch between charging and discharging of the detection electrode. The electrode capacitance conversion circuit outputs a first measurement value determined by the charging and discharging of the detection electrode. The stray capacitance conversion circuit has the almost same configuration as the electrode capacitance conversion circuit so as to output a second measurement value corresponding to a stray capacitance of the electrode capacitance conversion circuit. The difference calculation circuit outputs a difference between the first and second measurement values.

### CROSS REFERENCE TO RELATED APPLICATION

This application is based on and incorporates herein by reference Japanese Patent Application No. 2009-53333 filed on Mar. 6, 2009.

### FIELD OF THE INVENTION

The present invention relates to a sensor for measuring a concentration of a material such as alcohol in a liquid.

Recently, alcohol blended gasoline has attracted great attention as a fuel for a vehicle for its low pollution characteristics. An optimum air-fuel ratio is different between pure gasoline and such blended gasoline. Therefore, accurate measurement of the concentration of alcohol in blended gasoline is important to achieve optimum control of an air-fuel ratio for blended gasoline.

A physical constant with a high change rate is generally used to accurately measure the concentration of alcohol in a liquid. In a conventional method, the concentration of alcohol is measured by detecting a change in relative permittivity of the liquid. For example, the change in the relative permittivity can be measured based on a change in capacitance. A conventional liquid concentration sensor has a pair of opposing electrodes located in the liquid and measure a change in capacitance between the electrodes, thereby measuring a change in the relative permittivity of the liquid. The electrodes are repeatedly charged and discharged by a switch that is turned ON and OFF at a constant period by a control circuit. An output voltage of the liquid concentration sensor changes in proportion to the concentration of alcohol in the liquid.

Assuming that the sensor output voltage is converted to digital by an A/D converter, the sensor output voltage may involve a conversion error (e.g., ±30 mV) due to characteristics of the A/D converter. The conversion error causes a measurement error in the ethanol concentration.

FIG. 9 depicts a relationship between an output voltage [V] of a conventional liquid concentration sensor and the concentration [wt %] of ethyl alcohol (ethanol). Ethanol has a temperature dependence, and also circuitry of the sensor has a temperature dependence. Therefore, as shown in FIG. 9, a relationship curve between the sensor output voltage and the ethanol concentration has a temperature dependence. That is, the relationship curve varies depending on ambient temperature.

In view of the temperature dependence, the measurement error in the ethanol concentration becomes large, when (e.g., at a point indicated by an arrow B in FIG. 9) the ambient temperature is high and the ethanol concentration is low. A reason for this is that the measurement error relative to the sensor output voltage is larger, as the gradient of a graph representing the relationship between the sensor output voltage and the ethanol concentration is smaller. Details are described below with reference to FIGS. 12A and 12B.

FIG. 12A depicts a measurement error ΔW1 in the ethanol concentration relative to an error ΔV1 in the sensor output voltage when the gradient of the relationship curve is relatively small. FIG. 12B depicts a measurement error ΔW2 in the ethanol concentration relative to the sensor output voltage error ΔV1 when the gradient of the relationship curve is relatively large. As can be seen by comparing FIGS. 12A and 12B, the measurement error ΔW1 is larger than the measurement error ΔW2. That is, the measurement error relative to the sensor output voltage error becomes larger, as the gradient of the relationship curve is smaller.

Therefore, the measurement error becomes large at a point (i.e., at the point indicated by the arrow B in FIG. 9) where the relationship curve is almost parallel to the horizontal axis.

The above problem may be solved by amplifying an output voltage. For example, JP-U-H4-75957 disclose a technique for representing an output signal as a linear function of a capacitance of a sensor portion by using a square circuit.

However, it is not always possible to simply amplify an output voltage, because the amplified voltage may exceed a saturation voltage of a circuit. For example, gain necessary to reduce the measurement error rate below one percent at the point where the relationship curve is almost parallel to the horizontal axis is about six times greater than the output voltage. As a result, the amplified voltage exceeds the saturation voltage. A reason for this is that the output voltage is increased (i.e., offset) due to a stray capacitance.

### SUMMARY OF THE INVENTION

In view of the above, it is an object of the present invention to provide a liquid concentration sensor for measuring a concentration of a material in a liquid by reducing an effect of a stray capacitance so that an output voltage can be amplified to a level large enough to reduce a measurement error.

According to an aspect of the present invention, a liquid concentration sensor includes an electrode capacitance conversion circuit, a stray capacitance conversion circuit, a difference calculation circuit, and an amplifier circuit. The electrode capacitance conversion circuit includes a detection electrode, switching devices, and an operation signal output device. The detection electrode has a pair of opposing terminals and is adapted to be partially located in a liquid fuel. The switching devices switch between charging and discharging of the detection electrode. The operation signal output device outputs an operation signal for turning ON and OFF the switching devices so that the electrode capacitance conversion circuit outputs a first measurement value that is determined by the charging and discharging of the detection electrode. The stray capacitance conversion circuit has the almost same configuration as the electrode capacitance conversion circuit so as to output a second measurement value corresponding to a stray capacitance of the electrode capacitance conversion circuit. The difference calculation circuit outputs a difference value between the first and second measurement values. The amplifier circuit amplifies the difference value.

### BRIEF DESCRIPTION OF THE DRAWINGS

The above and other objectives, features and advantages of the present invention will become more apparent from the following detailed description made with check to the accompanying drawings. In the drawings:

FIG. 1 is a block diagram illustrating an alcohol concentration sensor according to an embodiment of the present invention;

FIG. 2 is a schematic diagram illustrating an electrode capacitance conversion circuit of the alcohol concentration sensor;

FIG. 3A is a schematic diagram illustrating an operation of the electrode capacitance conversion circuit when a pulse signal is at a LOW level, and FIG. 3B is a schematic diagram illustrating an operation of the electrode capacitance conversion circuit when the pulse signal is at a HIGH level;

FIG. 4 is a timing chart illustrating electric currents produced in the electrode capacitance conversion circuit;

FIG. 5 is a timing chart illustrating an output voltage of the electrode capacitance conversion circuit;

FIG. 6 is a schematic diagram illustrating a stray capacitance conversion circuit of the alcohol concentration sensor;

FIG. 7 is a schematic diagram illustrating a modification of the stray capacitance conversion circuit;

FIG. 8 is a schematic diagram illustrating a differential amplifier of the alcohol concentration sensor;

FIG. 9 is diagram illustrating a relationship curve between the concentration of methanol and an output voltage of a conventional alcohol concentration sensor;

FIG. 10 is a diagram illustrating a relationship curve between the concentration of methanol and an output voltage of the alcohol concentration sensor of FIG. 1 in which the stray capacitance conversion circuit of FIG. 7 is used;

FIG. 11 is a diagram illustrating a relationship curve between the concentration of methanol and an output voltage of the alcohol concentration sensor of FIG. 1 in which the stray capacitance conversion circuit of FIG. 6 is used; and

FIG. 12A is a diagram illustrating a measurement error relative to an output voltage error when the gradient of a relationship curve between the concentration of methanol and an output voltage is relatively small, and FIG. 12B is a diagram illustrating a measurement error relative to an output voltage error when the gradient of the relationship curve is relatively large.

### DETAILED DESCRIPTION OF THE PREFERRED EMBODIMENT

An alcohol concentration sensor 1 according to an embodiment of the present invention is described below with reference to the drawings. For example, the alcohol concentration sensor 1 can be mounted on a vehicle to measure the concentration of ethanol in blended gasoline used as a fuel for the vehicle.

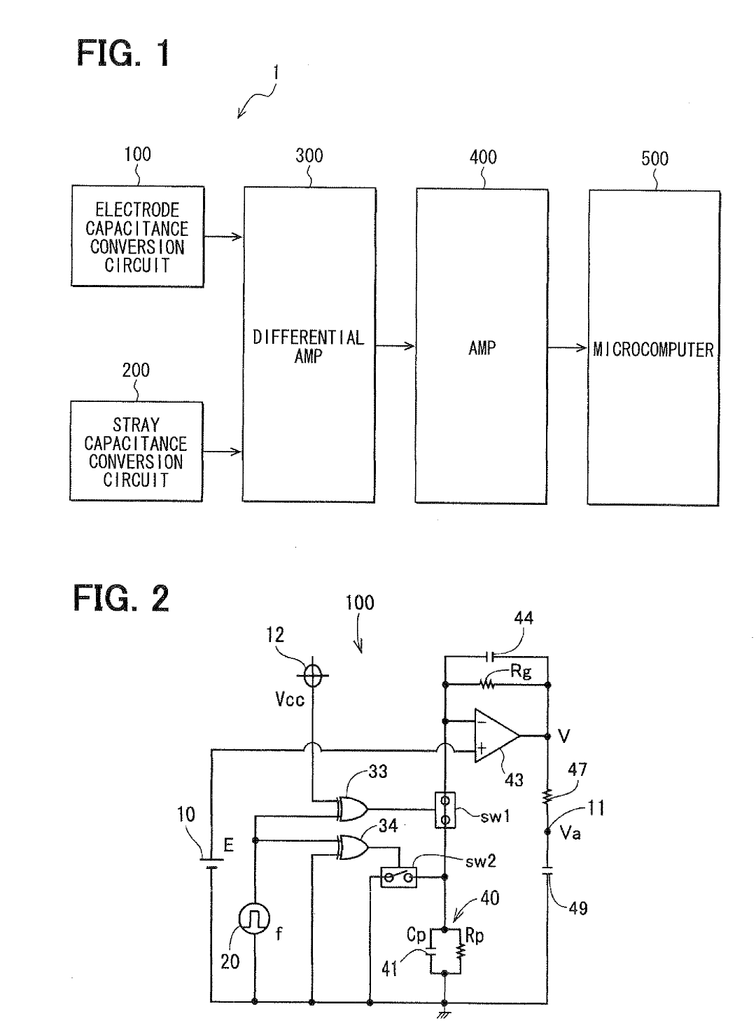

FIG. 1 is a block diagram of the alcohol concentration sensor 1. The alcohol concentration sensor 1 includes an electrode capacitance conversion circuit 100, a stray capacitance conversion circuit 200, a differential amplifier 300, an amplifier circuit 400, and a microcomputer 500.

The electrode capacitance conversion circuit 100 outputs a first measurement voltage corresponding to a capacitance including a stray capacitance existing in electrodes and circuitry. The stray capacitance conversion circuit 200 outputs a second measurement voltage corresponding to the stray capacitance. The differential amplifier 300 outputs a difference voltage between the first measurement voltage and the second measurement voltage, thereby canceling the effect of the stray capacitance. The amplifier circuit 400 amplifies the difference voltage to a suitable level. The amplified voltage is inputted to the microcomputer 500.

Firstly, the electrode capacitance conversion circuit 100 is discussed in detail below. FIG. 2 is a schematic diagram of the electrode capacitance conversion circuit 100.

The electrode capacitance conversion circuit 100 has an output terminal 11 for outputting a first measurement voltage Va. The first measurement voltage Va is measured with respect to a reference voltage E. For example, the reference voltage E can be 1 volts (V).

The electrode capacitance conversion circuit 100 includes an oscillation section 20 and a detection section 40. The oscillation section 20 outputs a pulse signal (as an operation clock signal) with a frequency f. For example, the oscillation section 20 can include a Schmitt trigger with hysteresis, a resistor connected in parallel to the Schmitt trigger, a capacitor connected between an input side of the Schmitt trigger and a ground potential.

As described later, the oscillation section 20 can output two types of pulse signals with different frequencies f1, f2. Therefore, for example, the oscillation section 20 can be formed with two sets of a Schmitt trigger, a resistor, and a capacitor that are configured in a manner described above.

The microcomputer 500 switches the frequency f of the pulse signal between the frequency f1 and the frequency f2. That is, the microcomputer 500 controls the oscillation section 20 so that the electrode capacitance conversion circuit 100 can operate on the pulse signal with the frequency f1 or the frequency f2.

The electrode capacitance conversion circuit 100 further includes a first switch sw1, a second switch sw2, a first EXOR gate 33, and a second EXOR gate 34. The first EXOR gate 33 is connected between the oscillation section 20 and the first switch sw1. Specifically, a first input of the first EXOR gate 33 is connected to the oscillation section 20, and an output of the first EXOR gate 33 is connected to the first switch sw1. The second EXOR gate 34 is connected between the oscillation section 20 and the second switch sw2. Specifically, a first input of the second EXOR gate 34 is connected to the oscillation section 20, and an output of the second EXOR gate 34 is connected to the second switch sw2. A second input of the first EXOR gate 33 is connected to a power source 12 so that a power supply voltage Vcc can be applied to the second input of the first EXOR gate 33. A second input of the second EXOR gate 34 is grounded. Thus, the first switch sw1 and the second switch sw2 are alternately and repeatedly turned ON and OFF at a period corresponding to the frequency f (i.e., f1 or f2) of the pulse signal outputted from the oscillation section 20.

The detection section 40 includes a detection electrode 41. The detection electrode 41 is located in a path over which a fuel of the vehicle flows. The detection electrode 41 has a pair of positive and negative terminals that are located opposite to each other to form a capacitance Cp. According to the embodiment, the concentration of ethanol in the fuel is measured by measuring the capacitance Cp of the detection electrode 41. It is noted that there is a leak resistance Rp that affects the measurement. It has been known that the leak resistance Rp depends on the amount of impurities in the fuel. Specifically, as the amount of impurities are increased, the leak resistance Rp is reduced. It can be considered that the leak resistance Rp is connected in parallel to the detection electrode 41. As described later, one advantage of the present embodiment is that the concentration of ethanol in the fuel can be measured without being affected by the leak resistance Rp.

The positive terminal of the detection electrode 41 is connected to an inverting input terminal of an operational amplifier 43 via the first switch sw1. A capacitor 44 and a gain resistance Rg are connected in parallel between an non-inverting input terminal and an output terminal of the operational amplifier 43. The reference voltage E is applied to the non-inverting input terminal of the operational amplifier 43. Further, the positive terminal of the detection electrode 41 is grounded via the second switch sw2, and the negative terminal of the detection electrode 41 is directly grounded.

The output terminal of the operational amplifier 43 is connected to the output terminal 11 via a resistor 47. The output terminal 11 is grounded via a capacitor 49. Thus, an output voltage V of the operational amplifier 43 is smoothed into the first measurement voltage Va.

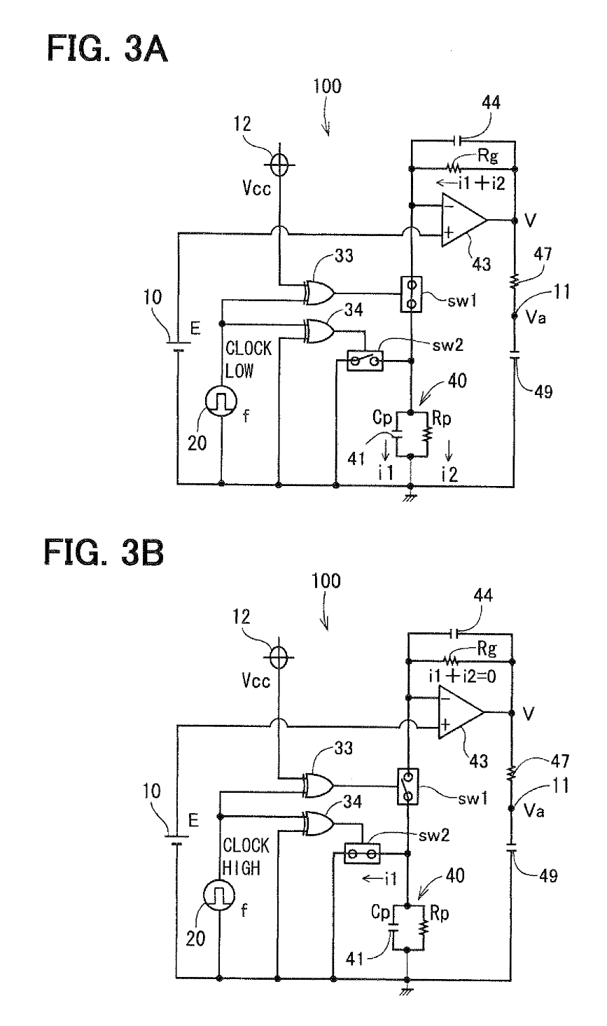

Next, an operation of the electrode capacitance conversion circuit 100 is discussed below with reference to FIGS. 3A, 3B, 4 and 5.

As described previously, the first switch sw1 and the second switch sw2 are alternately and repeatedly turned ON and OFF at the period corresponding to the frequency f (i.e., f1 or f2) of the pulse signal (i.e., operation clock signal) outputted from the oscillation section 20.

As shown in FIG. 3A, when the pulse signal is at a logic Low level, the first switch sw1 is turned ON, and the second switch sw2 is turned OFF. Specifically, the first input of the first EXOR gate 33 is ture “1” (i.e., the power supply voltage Vcc), but the second input of the first EXOR gate 33 is false “0” (i.e., the pulse signal). As a result, the output of the first EXOR gate 33 becomes true “1” so that the first switch sw1 can be turned ON. In contrast, the first input of the second EXOR gate 34 is false “0” (i.e., the ground potential), and also the second input of the second EXOR gate 34 is false “0” (i.e., the pulse signal). As a result, the output of the second EXOR gate 34 becomes false “0” so that the second switch sw2 can be turned OFF.

In this case, the operational amplifier 43 acts in such a manner that the inverting and non-inverting input terminals of the operational amplifier 43 are at the same potential. Consequently, as shown in FIG. 3A, an electric current i1+i2 flows through the gain resistance Rg due to the reference voltage E. The electric current i1+i2 includes a first current i1 flowing though the detection electrode 41 and a second current i2 flowing through the leak resistance Rp.

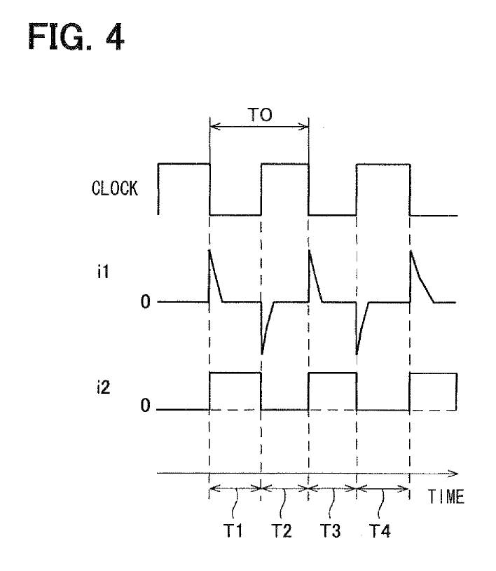

In FIG. 4, time periods T1, T3 correspond to FIG. 3A. As shown in FIG. 4, during the time periods T1, T3, the first current i1 rises initially and becomes zero when the detection electrode 41 is fully charged. The second current i2 rises at the same time as the first current i1 and remains constant during the time periods T1, T3. To be exact, the total current i1+i2 remains constant, and the rising of the second current i2 is delayed with respect to the rising of the first current i1.

As shown in FIG. 3B, when the pulse signal is at a logic High level, the first switch sw1 is turned OFF, and the second switch sw2 is turned ON. Specifically, the first input of the first EXOR gate 33 is ture “1” (i.e., the power supply voltage Vcc), and the second input of the first EXOR gate 33 is true “1” (i.e., the pulse signal). As a result, the output of the first EXOR gate 33 becomes false “0” so that the first switch sw1 can be turned OFF. In contrast, the first input of the second EXOR gate 34 is false “0” (i.e., the ground potential), but the second input of the second EXOR gate 34 is true “1” (i.e., the pulse signal). As a result, the output of the second EXOR gate 34 becomes true “1” so that the second switch sw2 can be turned ON.

Since the positive terminal of the detection electrode 41 is grounded via the second switch sw2, the charged detection electrode 41 can be discharged. Therefore, the current i1 flows through the detection electrode 41 in opposite direction compared to when the pulse signal is at a logic Low level.

In FIG. 4, time periods T2, T4 correspond to FIG. 3B. As shown in FIG. 4, during the time periods T2, T4, the first current i1 rises in opposite direction compared to when the pulse signal is at a logic Low level and becomes zero when the charged detection electrode 41 is fully discharged. The second current i2 is zero during the time periods T2, T4.

Next, the output voltage V of the operational amplifier 43 produced when the first and second switches sw1,sw2 are switched by the pulse signal with the frequency f is discussed below.

From FIG. 4, an average value of the second current i2 can be given as follows:

i2=0.5E/Rp (1)

Charge stored in the detection electrode 41 can be given as follows by using the capacitance Cp of the detection electrode 41:

ΔQ=CpE (2)

Since an average value of the first current i1 is the derivative of the charge, the average value of the first current i1 can be given as follows:

i1=ΔQ/T0=CpE/T0=CpEf (3)

In the equation (3), T0 (=1/f) represents a period of the pulse signal.

Therefore, the output voltage V of the operational amplifier 43 can be given as follows by using the equations (1), (3):

$$\begin{matrix}V = E + Rg ( i 1 + i 2 ) \\ = E + Rg ( CpE / T 0 + 0.5 E / Rp ) \\ = E ( 1 + 0.5 Rg / Rp + fRgCp )\end{matrix} \qquad ( 4 )$$

It can be seen from the equation (4) that the output voltage V does not vary when the leak resistance Rp is close to infinity. In such a case, the ethanol concentration can be accurately measured. However, when the leak resistance Rp is small (i.e., when the fuel contains a lot of impurities), the measurement error becomes larger.

According to the embodiment, the first and second switches sw1, sw2 are turned ON and OFF by the pulse signal with the frequency f1 to obtain an output voltage V(f1) of the operational amplifier 43. Further, the first and second switches sw1, sw2 are turned ON and OFF by the pulse signal with the frequency f2 to obtain an output voltage V(f2) of the operational amplifier 43. The effect of the leak resistance Rp can be removed by taking a difference between the output voltages V(f1), V(f2). From the equation (4), the difference V(f1)-V(f2) can be given as follows:

V(f1)−V(f2)=E·(f1−f2)·Rg·Cp (5)

Thus, the capacitance Cp of the detection electrode 41 can be measured from the equation (5) without being affected by the leak resistance Rp.

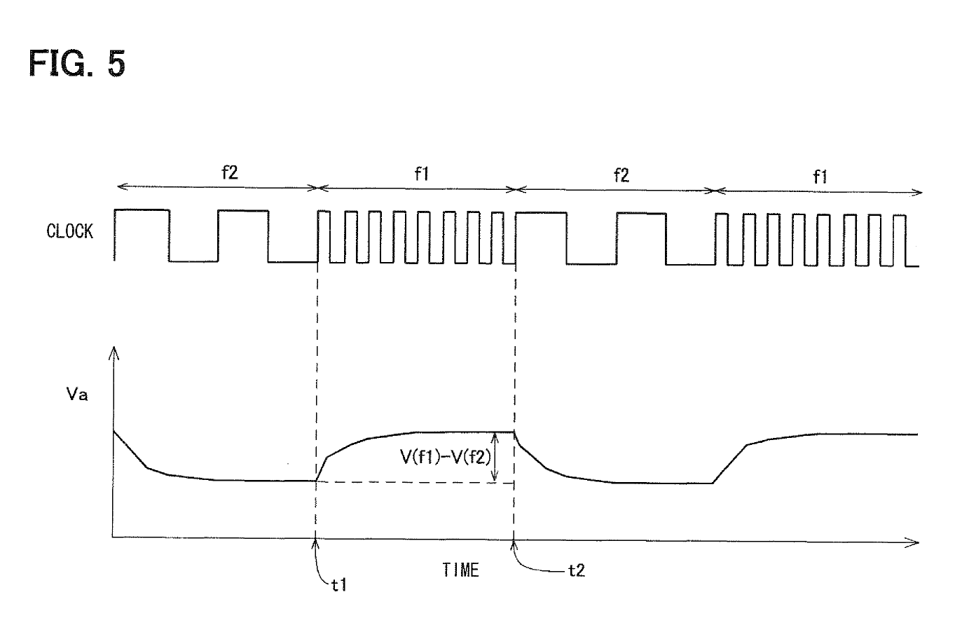

FIG. 5 is an example of a timing chart of the first measurement voltage Va outputted from the output terminal 11 of the electrode capacitance conversion circuit 100. The output voltage V of the operational amplifier 43 is smoothed into the first measurement voltage Va by the resistor 47 and the capacitor 49. That is, the resistor 47 and the capacitor 49 forms a smoothing circuit. In FIG. 5, initially, the first and second switches sw1, sw2 are turned ON and OFF by the pulse signal with the frequency f2 so that the operational amplifier 43 can output the voltage V(f2). The first measurement voltage Va almost converges by a time t1. Then, from the time t1, the first and second switches sw1, sw2 are switched by the pulse signal with the frequency f1 so that the operational amplifier 43 can output the voltage V(f1). The first measurement voltage Va almost converges by a time t2. The microcomputer 500 switches the frequency f of the pulse signal between the frequencies f1, f2 based on a change in the voltage Va such as shown in FIG. 5.

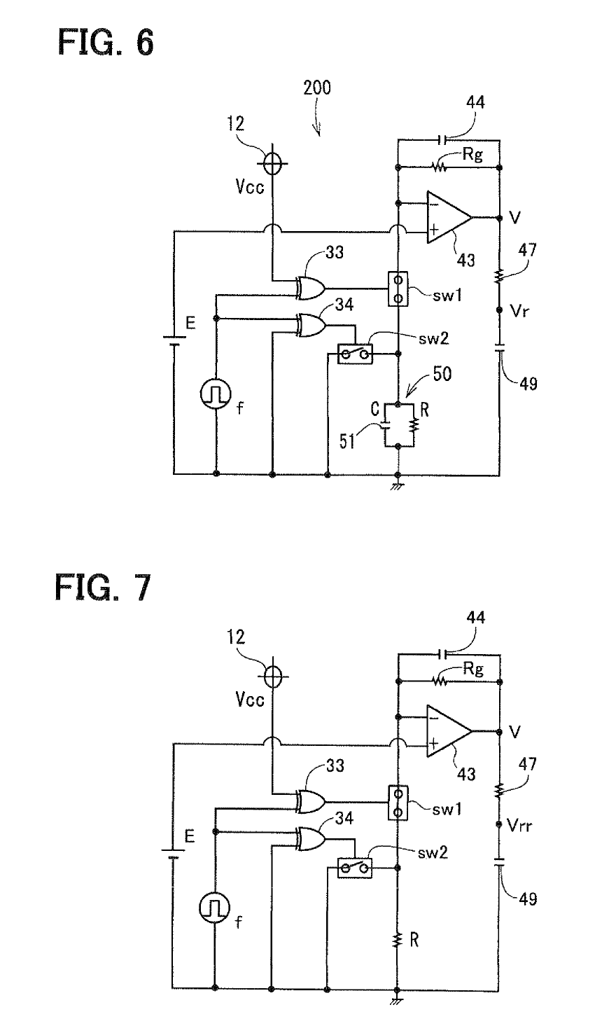

Next, the stray capacitance conversion circuit 200 is discussed in detail below with reference to FIGS. 6 and 7. FIG. 6 is a schematic diagram of a first example of the stray capacitance conversion circuit 200. FIG. 7 is a schematic diagram of a second example of the stray capacitance conversion circuit 200.

As can be seen by comparing FIG. 2 and FIG. 6, the first example of the stray capacitance conversion circuit 200 has almost the same configuration as the electrode capacitance conversion circuit 100.

A difference between the electrode capacitance conversion circuit 100 and the first example of the stray capacitance conversion circuit 200 is in that the stray capacitance conversion circuit 200 has a dummy detection section 50 instead of the detection section 40. The dummy detection section 50 includes a dummy detection electrode 51 and a resistance R connected in parallel to the dummy detection electrode 51. It is noted that the dummy detection electrode 51 is entirely located outside the fuel. The dummy detection electrode 51 has a capacitance C corresponding to a capacitance of a portion of the detection electrode 41 located outside the fuel. Since the capacitance of the portion of the detection electrode 41 located outside the fuel has an almost constant value, the capacitance C of the dummy detection electrode 51 can be determined by a statistical method. The resistance R is adjusted according to a resistance (generally very small) of a first switch sw1.

As can be seen by comparing FIG. 6 and FIG. 7, a difference between the first and second examples of the stray capacitance conversion circuit 200 is that the second example of the stray capacitance conversion circuit 200 has no dummy detection electrode 51.

It is noted that the stray capacitance affecting the measurement is caused from the electrode capacitance conversion circuit 100 itself and a portion of the detection electrode 41 located outside the fuel.

When the second example of the stray capacitance conversion circuit 200 shown in FIG. 7 is used, the stray capacitance due to the electrode capacitance conversion circuit 100 itself can be measured. Specifically, the second example of the stray capacitance conversion circuit 200 is controlled using the two pulse signals having different frequencies f1, f2 in the same manner as the electrode capacitance conversion circuit 100. In such an approach, the second example of the stray capacitance conversion circuit 200 can output a second measurement voltage Vrr corresponding to the stray capacitance of the electrode capacitance conversion circuit 100 itself. Therefore, the effect of the stray capacitance due to the electrode capacitance conversion circuit 100 itself can be removed by taking the difference between the first measurement voltage Va and the second measurement voltage Vrr using the differential amplifier 300.

In contrast, when the first example of the stray capacitance conversion circuit 200 shown in FIG. 6 is used, not only the stray capacitance due to the electrode capacitance conversion circuit 100 itself but also the stray capacitance due to the portion of the detection electrode 41 located outside the fuel can be measured. Specifically, the first example of the stray capacitance conversion circuit 200 is controlled using the two pulse signals having different frequencies f1, f2 in the same manner as the electrode capacitance conversion circuit 100. In such an approach, the first example of the stray capacitance conversion circuit 200 can output a second measurement voltage Vr corresponding to not only the stray capacitance of the electrode capacitance conversion circuit 100 itself but also the stray capacitance due to the portion of the detection electrode 41 located outside the fuel. Therefore, the effect of each stray capacitance can be removed by taking the difference between the first measurement voltage Va and the second measurement voltage Vr using the differential amplifier 300.

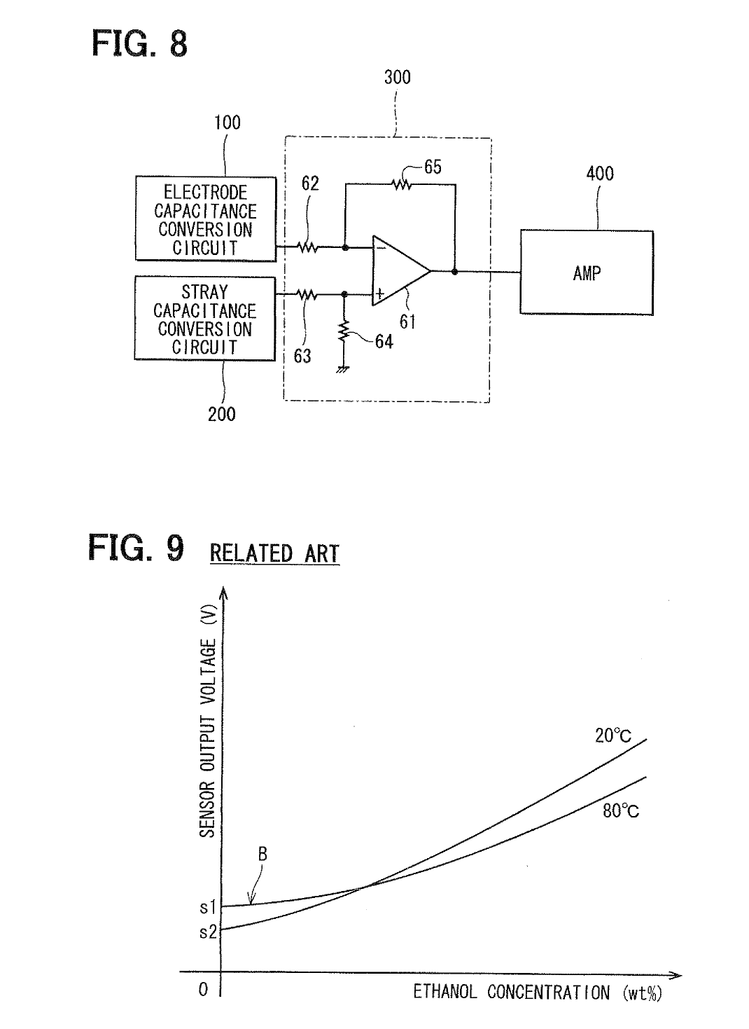

Next, the differential amplifier 300 is discussed in detail below with reference to FIG. 8. As shown in FIG. 8, the differential amplifier 300 includes an operational amplifier 61 and multiple resistors 62-65.

Specifically, the output terminal 11 of the electrode capacitance conversion circuit 100 is connected to an inverting input terminal of the operational amplifier 61 via the resistor 62. The output terminal of the stray capacitance conversion circuit 200 is connected to an non-inverting input terminal of the operational amplifier 61 via the resistor 63. Further, the non-inverting input terminal of the operational amplifier 61 is grounded via the resistor 64. Furthermore, the output terminal of the operational amplifier 61 is connected to the amplifier circuit 400 and connected to the inverting input terminal of the operational amplifier 61. Thus, the difference between the first measurement voltage Va outputted from the electrode capacitance conversion circuit 100 and the second measurement voltage Vr or Vrr outputted from the stray capacitance conversion circuit 200 is inputted to the amplifier circuit 400.

Next, advantages of the alcohol concentration sensor 1 are discussed below.

As described previously, FIG. 9 depicts the relationship between the output voltage of the conventional liquid concentration sensor and the ethanol concentration. In FIG. 9, there are two relationship curves, one of which corresponds to ambient temperature of 20° C., and the other of which corresponds to ambient temperature of 80° C. As can be seen from FIG. 9, even when the ethanol concentration is zero, the sensor output voltage is not zero. That is, the sensor output voltage is offset due to stray capacitance of the sensor. Specifically, the offset voltage is s1 at the ambient temperature of 80° C. and s2 at the ambient temperature of 20° C. In this way, the offset voltage varies depending on the ambient temperature. A reason for this is that an electrode capacitance conversion circuit of the sensor has a temperature dependence, and the stray capacitance varies depending on the ambient temperature due to the temperature dependence. The offset voltages s1, s2 are caused by not only the stray capacitance of the electrode capacitance conversion circuit itself but also a portion of a detection electrode located outside a fuel.

According to the embodiment, the effect of the stray capacitance of the electrode capacitance conversion circuit 100 itself can be removed by using the stray capacitance conversion circuit 200 shown in FIG. 7.

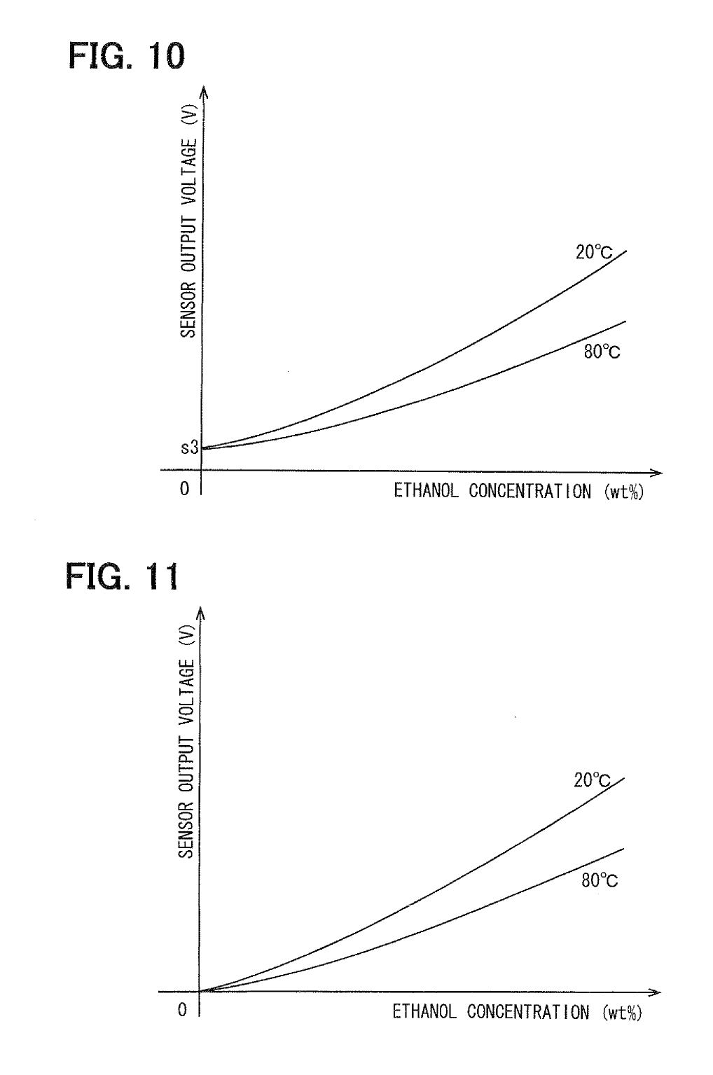

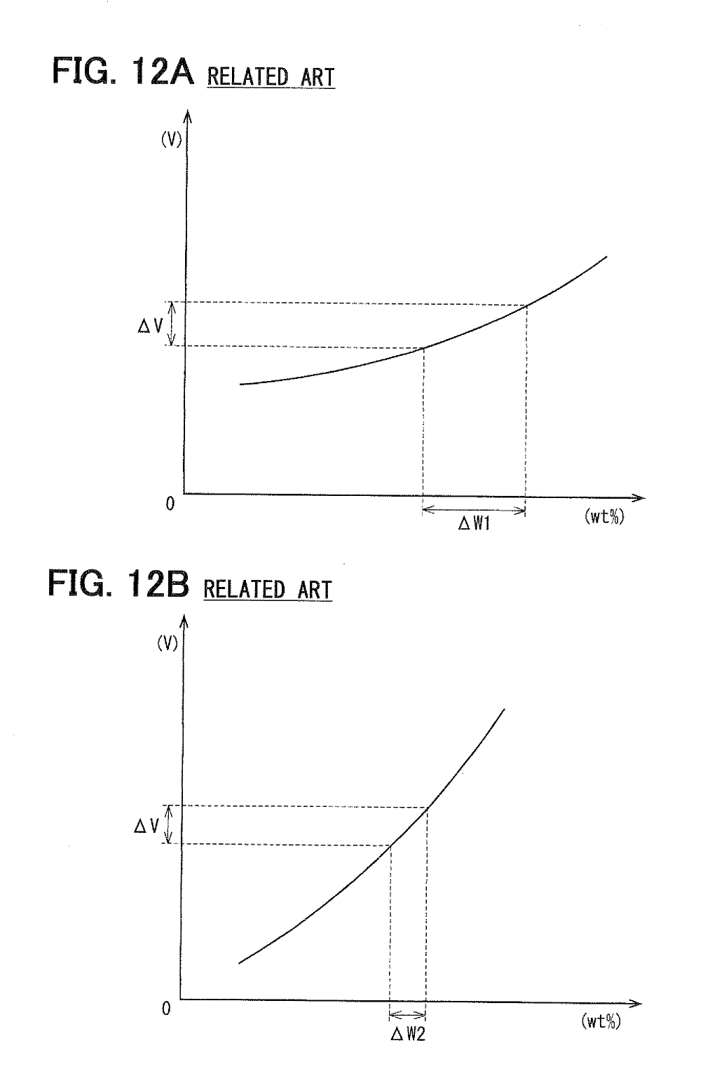

FIG. 10 depicts a relationship curve between the concentration of ethanol and an output voltage of the differential amplifier 300 of the alcohol concentration sensor 1 in which the stray capacitance conversion circuit 200 shown in FIG. 7 is used. It can be seen from FIG. 10 that an offset voltage is constant at s3 regardless of the ambient temperature. That is, FIG. 10 indicates that the output voltage of the differential amplifier 300 is not affected by the stray capacitance of the electrode capacitance conversion circuit 100 itself. The offset voltage s3 is caused from the stray capacitance of the portion of the detection electrode 41 located outside the fuel.

Further, according to the embodiment, the effect of the stray capacitance of the portion of the detection electrode 41 located outside the fuel can be removed by using the stray capacitance conversion circuit 200 shown in FIG. 6.

FIG. 11 depicts a relationship curve between the concentration of ethanol and the output voltage of the differential amplifier 300 of the alcohol concentration sensor 1 in which the stray capacitance conversion circuit 200 shown in FIG. 6 is used. It can be seen from FIG. 11 that the offset voltage is very small (almost zero) regardless of the ambient temperature. That is, FIG. 11 indicates that the output voltage of the differential amplifier 300 is affected by neither the stray capacitance of the portion of the detection electrode 41 located outside the fuel nor the stray capacitance of the electrode capacitance conversion circuit 100 itself.

Since the offset voltage is very small, the output voltage of the differential amplifier 300 is relatively small. Therefore, the output voltage of the differential amplifier 300 can be amplified by the amplifier circuit 400 to a level large enough to reduce the measurement error in the ethanol concentration as much as possible.

The oscillation section 20 can serve as an operation signal output device. The differential amplifier 300 can serve as a difference calculation circuit. The dummy detection electrode 51 can serve as a capacitor with a capacitance corresponding to a capacitance of a portion of the detection electrode 41 located outside the fuel. The resistance R of the dummy detection section 50 can serve as a resistor with a resistance corresponding to a resistance of the switching devices sw1, sw2.

(Modifications)

The embodiment described above can be modified in various ways.

For example, four switches that are connected in a so-called crawl type configuration can be used instead of the two switches sw1, sw2.

The present invention can be applied to a liquid concentration sensor for measuring the concentration of a material other than ethanol. For example, the present invention can be applied to a liquid concentration sensor for measuring the concentration of methyl alcohol (methanol).

Such changes and modifications are to be understood as being within the scope of the present invention as defined by the appended claims.

What is claimed is:

1. A sensor for measuring a concentration of a material in a liquid fuel, the sensor comprising:
an electrode capacitance conversion circuit including a detection electrode having a pair of opposing terminals and adapted to be partially located in the fuel, the electrode capacitance conversion circuit further including a plurality of switching devices configured to switch between charging and discharging of the detection electrode, and an operation signal output device configured to output an operation signal for turning ON and OFF the plurality of switching devices so that the electrode capacitance conversion circuit outputs a first measurement value that is determined by the charging and discharging of the detection electrode;
a stray capacitance conversion circuit configured in the almost the same manner as the electrode capacitance conversion circuit so as to output a second measurement value corresponding to a stray capacitance of the electrode capacitance conversion circuit;
a difference calculation circuit configured to output a difference value between the first and second measurement values; and
an amplifier circuit configured to amplify the difference value.

2. The sensor according to claim 1, wherein
the stray capacitance conversion circuit has no detection electrode, and
the stray capacitance conversion circuit has a resistor with a resistance corresponding to a resistance of the plurality of switching devices.

3. The sensor according to claim 2, wherein
the stray capacitance conversion circuit has a capacitor with a capacitance corresponding to a capacitance of a portion of the detection electrode of the electrode capacitance conversion circuit, the portion being adapted to be located outside the fuel.

4. The sensor according to claim 1, wherein
the operation signal comprises a first signal with a first frequency for turning ON and OFF the plurality of switching devices at a first period and a second signal with a second frequency for turning ON and OFF the plurality of switching devices at a second period, and
the electrode capacitance conversion circuit outputs the first measurement value based on the first and second signals, and
the stray capacitance conversion circuit outputs the second measurement value based on the first and second signals.

5. The sensor according to claim 1, wherein
each of the electrode capacitance conversion circuit and the stray capacitance conversion circuit includes a smoothing device, and
each of the first and second measurement values is smoothed by the smoothing device.
